(19) United States
(12) Patent Application Publication
(10) Pub. No.: US 2026/0078484 A1
(43) Pub. Date: Mar. 19, 2026

(54) LAYERED METAL OXIDE-SILICON OXIDE FILMS

(71) Applicant: Lam Research Corporation, Fremont, CA (US)

(72) Inventors: Pulkit AGARWAL, Beaverton, OR (US); Pei-Chi LIU, Portland, OR (US); Ravi KUMAR, Beaverton, OR (US); Jennifer Leigh PETRAGLIA, Portland, OR (US); Easwar SRINIVASAN, Portland, OR (US); Bart J. VAN SCHRAVENDIJK, Palo Alto, CA (US)

(21) Appl. No.: 19/110,207

(22) PCT Filed: Sep. 5, 2023
(86) PCT No.: PCT/US2023/073490

§ 371 Date: Mar. 10, 2025

Related U.S. Application Data
(60) Provisional application No. 63/377,490, filed on Sep. 28, 2022.

(51) Int. Cl. C23C 16/40; C23C 16/455; H01L 21/02

(52) U.S. Cl. CPC C23C 16/401; C23C 16/45529; H10P 14/6304; H10P 14/6529; H10P 14/69215

(57) ABSTRACT

Examples are disclosed that relate to layered metal oxide films. One example provides a method of forming a patterning structure. The method comprises performing one or more layered film deposition cycles to form a layered film comprising a metal oxide. A layered film deposition cycle of the one or more layered deposition cycles comprises a metal oxide deposition subcycle and a silicon oxide deposition cycle. The metal oxide deposition subcycle comprises exposing the substrate to a metal-containing precursor and oxidizing metal-containing precursor adsorbed to the substrate. The silicon oxide deposition subcycle comprising exposing a substrate to a silicon-containing precursor and oxidizing silicon-containing precursor adsorbed to the substrate. The method further comprises etching one or more regions of the layered film to form the patterning structure.

### BACKGROUND

Semiconductor device fabrication processes may involve many steps of material deposition, patterning and removal to form integrated circuits on substrates. For example, the fabrication of small feature sizes in a patterning process may involve the deposition and etching of films to form spacers that define feature locations.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

One example provides a method of forming a patterning structure. The method comprises performing one or more layered film deposition cycles to form a layered film comprising a metal oxide. A layered film deposition cycle of the one or more layered film deposition cycles comprises a metal oxide deposition subcycle. The metal oxide deposition subcycle comprises exposing the substrate to a metal-containing precursor and oxidizing metal-containing precursor adsorbed to the substrate. The layered film deposition cycle further comprises a silicon oxide deposition subcycle. The silicon oxide deposition cycle comprises exposing a substrate to a silicon-containing precursor and oxidizing the silicon-containing precursor adsorbed to the substrate. The method further comprises etching one or more regions of the layered film to form the patterning structure.

In some such examples, the method comprises performing a plurality of layered film deposition cycles.

In some such examples, the layered film deposition cycle of the one or more layered film deposition cycles alternatively or additionally comprises a greater number of silicon oxide deposition subcycles than metal oxide deposition subcycles.

In some such examples, the layered film deposition cycle of the one or more layered film deposition cycles alternatively or additionally comprises a greater number of metal oxide deposition cycles than silicon oxide deposition subcycles.

In some such examples, the layered film deposition cycle of the one or more layered film deposition cycles alternatively or additionally comprises an equal number of silicon oxide deposition cycles and metal oxide subcycles.

In some such examples, etching the one or more regions of the layered film to form the patterning structure alternatively or additionally comprises etching the one or more regions of the layered film to form a spacer for a self-aligned patterning process.

In some such examples, forming the spacer alternatively or additionally comprises forming the layered film over a mandrel, and removing the mandrel after etching the one or more regions of the layered film.

In some such examples, the metal-containing precursor alternatively or additionally comprises one or more of aluminum, molybdenum, tungsten, or titanium.

In some such examples, the metal-containing precursor alternatively or additionally comprises one or more of an aluminum halide, aluminum alkoxide, trimethyl aluminum, aluminum hydride, aluminum carbonyl, tungsten hexafluoride, tungsten hexachloride, tungsten hexacarbonyl, bis(tert-butylimino)bis(dimethylamino) tungsten, bis(tert-butylimino)bis(dimethylamino) molybdenum, molybdenum pentachloride, molybdenum dioxide dichloride, molybdenum oxytetrachloride, molybdenum hexacarbonyl, titanium tetrachloride, or titanium isopropoxide.

In some such examples, forming the patterning structure alternatively or additionally comprises forming a patterning structure comprising a modulus within a range of 90 to 200 gigapascals (GPa).

In some such examples, forming the patterning structure alternatively or additionally comprises forming a patterning structure comprising a width within a range of 10 Angstroms to 100 Angstroms.

In some such examples, the patterning structure alternatively or additionally comprises a dimension normal to the plane of the substrate surface within a range of 30 Angstroms-500 Angstroms.

In some such examples, the method alternatively or additionally comprises cleaning metal oxide residue and silicon oxide residue from the processing chamber using a plasma clean comprising a fluorine-containing species.

Another example provides a processing tool that comprises a processing chamber, one or more gas inlets into the processing chamber. The processing tool further comprises flow control hardware configured to control gas flow through the one or more gas inlets. The processing tool further comprises a controller configured to operate the processing tool to perform one or more layered film deposition cycles. In a silicon oxide deposition subcycle of the layered film deposition cycle, the controller is configured to control the flow control hardware to introduce a silicon-containing precursor into the processing chamber and control the flow control hardware to form oxidizing conditions in the processing chamber. In a metal oxide deposition subcycle of the layered film deposition cycle, the controller is configured to control the flow control hardware to introduce a metal-containing precursor into the processing chamber, the metal-containing precursor comprising one or more of molybdenum or tungsten, and control the flow control hardware to form oxidizing conditions in the processing chamber.

In some such examples, the controller is alternatively or additionally configured to control the processing tool to perform a greater number of silicon oxide deposition subcycles than metal oxide deposition cycles in a layered film deposition cycle of the one or more layered film deposition cycles.

In some such examples, the controller is alternatively or additionally configured to control the processing tool to perform a greater number of metal oxide deposition subcycles than silicon oxide subcycles in a layered film deposition cycle of the one or more layered film deposition cycles.

In some such examples, the controller is alternatively or additionally configured to control the processing tool to perform one or more layered film deposition cycles to grow a layered film comprising a thickness of between 10-100 Angstroms.

Another example provides an intermediate structure in a self-aligned patterning process. The intermediate structure comprises a substrate and a pattern of metal oxide and silicon oxide-containing spacers disposed on the substrate.

In some such examples, a spacer of the pattern of metal oxide and silicon oxide-containing spacers alternatively or additionally comprises a width within a range of 100 Angstroms to 10 Angstroms.

In some such examples, the metal oxide alternatively or additionally comprises one or more of aluminum, tungsten, molybdenum or titanium.

### BRIEF DESCRIPTION OF THE DRAWINGS

FIGS. 1A-1D schematically show an example spacer fabrication process in which spacers are formed from silicon oxide without a metal oxide.

FIG. 2 shows a block diagram of an example processing tool.

FIGS. 3A-3B show a flow diagram illustrating an example process to form a patterning structure using self-aligned patterning.

FIGS. 4A-4E schematically show an example spacer fabrication process in which spacers are formed from a layered film comprising silicon oxide and a metal oxide.

FIGS. 5A-5E schematically show an example gapfill process using a layered film to form patterning features.

FIG. 6 shows a block diagram of an example computing device.

### DETAILED DESCRIPTION

The term “atomic layer deposition” (ALD) may generally represent a process in which a film (e.g., an oxide film) is formed on a substrate in one or more individual layers by sequentially adsorbing a precursor to a substrate and then chemically transforming the adsorbed precursor to form a film layer. Examples of ALD processes comprise plasma-enhanced ALD (PEALD) and thermal ALD (TALD). PEALD and TALD respectively utilize a plasma of a reactive gas and heat to facilitate a chemical conversion of a precursor adsorbed to a substrate to a film on the substrate. The terms “growth” and “deposition”, and variants thereof, also may be used to refer to film formation.

The terms “atomic layer deposition cycle” and “ALD cycle” may generally represent a single cycle of adsorbing a chemical precursor on a substrate surface and then chemically transforming the adsorbed chemical precursor to form a film layer on the substrate. The term “metal oxide deposition subcycle” may generally represent an ALD cycle used to deposit metal oxide in a layered film. The term “silicon oxide deposition subcycle” may generally represent an ALD cycle used to deposit silicon oxide in a layered film.

The term “chemical vapor deposition” (CVD) may generally represent a process in which a film is formed on a substrate by a continuous flow of reactive gas phase precursors. Plasma-enhanced CVD (PECVD) utilizes a plasma to form reactive species from the gas phase precursors to facilitate film formation. Thermal CVD (TCVD) utilizes heat to facilitate film formation.

The terms “etch”, “etching” and variants thereof may generally represent a process of removing material from a substrate surface. An etching process may encompass chemical and/or physical material removal mechanisms. A dry etching process is an etching process that utilizes gas phase etchants. A wet etching process is an etching process that utilizes liquid-phase etchants.

The term “fluorine-containing species” may generally represent a chemical entity comprising fluorine. Examples of fluorine-containing species include molecules comprising fluorine (e.g. NFₓH₃₋ₓ, CFₓH₄₋ₓ, C₂FₓH₆₋ₓ, HF, F₂), ionic and radical variants of molecules comprising fluorine, fluoride ions, and fluorine radicals.

The term “hardmask” may generally represent a film that is more resistant to etching than polymer photoresists. Examples of hardmask materials may include silicon nitride, silicon oxynitride, silicon carbonitride and silicon oxycarbide films.

The term “intermediate structure” may generally represent a structure formed by earlier processing steps that is modified in later processing steps.

The term “layered film” may generally represent a laminate structure comprising at least one silicon oxide film layer alternating with at least one metal oxide film layer. A metal oxide film layer is formed by performing one or more metal oxide ALD subcycles. A silicon oxide film layer is formed by performing one or more silicon oxide ALD subcycles.

The term “layered film deposition cycle” may generally represent a sequence of ALD cycles that includes one or more silicon oxide deposition subcycles to form a silicon oxide layer of a layered film, and that also includes one or more metal oxide deposition subcycles to form a metal oxide layer of a layered film. One layered film deposition cycle forms one silicon oxide layer and one metal oxide layer. One or more layered film deposition cycles may be used to form a layered film. A thickness of the silicon oxide layer formed in a layered film deposition cycle is dependent upon a number of silicon oxide deposition subcycles used to form the silicon oxide layer. A thickness of the metal oxide layer formed in a layered film deposition cycle is dependent upon a number of metal oxide deposition cycles used to form the metal oxide layer. For example, a layered film comprising one silicon oxide layer and one overlaying metal oxide layer is formed by performing m silicon oxide deposition subcycles followed by n metal oxide deposition cycles, where m and n are integers independently equal to or greater than 1. A proportion of silicon oxide and metal oxide in such a film can be adjusted by varying m and n. As another example, a layered film comprising a silicon oxide layer, a metal oxide layer, another silicon oxide layer, and then another metal oxide layer is formed by performing m silicon oxide deposition subcycles, n metal oxide deposition cycles, o, silicon oxide deposition cycles, and p metal oxide deposition cycles where m, n, o, and p are integers independently equal to or greater than 1.

The term “layered silicon oxide-metal oxide film” may generally represent a laminate structure comprising one or more silicon oxide film layers alternating with one or more metal oxide film layers.

The term “low temperature silicon oxide (LT-oxide)” may generally represent silicon dioxide films formed at deposition temperatures below 300° C. LT-oxide may exhibit higher deposition rates than films formed at deposition temperatures greater than 300° C., under otherwise similar conditions.

The term “mandrel” may generally represent a raised structure in a patterning process with sidewalls that define locations of spacers. Mandrels may comprise any suitable material. Examples may include polycrystalline silicon, amorphous silicon, silicon oxides, silicon nitrides, photoresists, spin on carbon and amorphous carbon.

The term “metal-containing precursor” may generally represent any material that can be introduced into a processing chamber and oxidized on a substrate surface to form a metal oxide film on the substrate surface. Examples of such metal-containing precursors may include aluminum-containing precursors for forming aluminum oxide (AlOₓ) films. Examples also may include molybdenum-containing precursors for forming molybdenum oxide (MoOₓ) films. Examples also may include titanium-containing precursors for forming titanium oxide (TiOₓ) films. Examples further may include tungsten-containing precursors for forming tungsten oxide (WOₓ) films.

Examples of aluminum-containing precursors may include aluminum halides (AlX_{y}), aluminum alkoxide (C₉H₂₁AlO₃), trimethyl aluminum (AlC₃H₉), aluminum carbonyl (Al(CO)ₓ), and aluminum hydride (AlH₃).

Examples of molybdenum-containing precursors may include bis(tert-butylimino)bis(dimethylamino) molybdenum (C₁₂H₃₀MoN₄), molybdenum pentachloride (MoCl₅), molybdenum dioxide dichloride(MoCl₅), molybdenum oxytetrachloride (MoOCl₄) and molybdenum hexacarbonyl (Mo(CO)₆).

Examples of titanium-containing precursors may include titanium tetrachloride (TCl₄) and titanium isopropoxide (Ti(OCH(CH₃)₂)₄).s

Examples of tungsten-containing precursors may include tungsten hexafluoride (WF₆), tungsten hexachloride (WCl₆), bis(tert-butylimino)bis(dimethylamino) tungsten (C₁₂H₃₀N₄W) and tungsten hexacarbonyl (W(CO)₆).

The term “metal oxide deposition subcycle” may generally represent a sequence of processes used to form a metal oxide-containing layer in a layered film.

The term “patterning structure” may generally represent a structure formed in an integrated circuit fabrication process that is used to generate topography on a substrate. Examples of patterning structures may include spacers.

The term “processing chamber” may generally represent an enclosure in which chemical and/or physical processes are performed on substrates. The pressure, temperature and atmospheric composition within a processing chamber may be controllable to perform the chemical and/or physical processes.

The term “processing tool” may generally represent a machine including a processing chamber and other hardware configured to enable processing to be carried out in the processing chamber.

The term “remote plasma” may generally represent a plasma used to produce chemical species at a location remote from a surface being processed with the chemical species. A remote plasma may be used to produce chemical species for processing a substrate that is located outside of the plasma. A remote plasma also may be used to produce chemical species for cleaning processing chamber surfaces that are located outside of the plasma.

The term “remote plasma enhanced atomic layer deposition” (remote PEALD) may generally represent an ALD process that utilizes a remote plasma to generate reactive gas species.

The term “remote plasma cleaning process” may generally represent a processing chamber cleaning process that utilizes a remote plasma to generate chemical species used for cleaning.

The term “self-aligned patterning” (SAP) may generally represent a sequence of process steps used to form spacers. A SAP process may comprise depositing a film on horizontal and sidewall surfaces of a mandrel. The SAP process may further comprise removing the film from horizontal surfaces. The SAP process may further comprise removing the mandrel. Removal of the mandrel leaves segments of the film that were formed on the sidewall surfaces of the mandrel. These segments are spacers. The term “self-aligned double patterning” (SADP) may generally represent a process comprising performing a single SAP process. The term “self-aligned quadruple patterning” (SAQP) may generally represent a process comprising performing two SAP processes to achieve a denser arrangement of spacers.

The term “silicon-containing precursor” may generally represent any material that can be introduced into a processing chamber in a gas phase to form a silicon-containing film on the substrate. Example silicon-containing precursors for forming silicon-containing films using PEALD may comprise materials having the general structure:

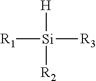

where R₁, R₂ and R₃ may be the same or different substituents, and may include silanes, siloxy groups, amines, halides, hydrogen, or organic groups, such as alkylamines, alkoxy, alkyl, alkenyl, alkynyl and aromatic groups.

More specific example silicon-containing precursors include polysilanes (H₃Si—(SiH₂)ₙ—SiH₃), where n ≥1, such as silane, disilane, trisilane, tetrasilane, and trisilylamine.

In some examples, the silicon-containing precursor is an alkoxysilane. Alkoxysilanes that may be used include the following: Hₓ—Si—(OR)_{y}, where x=1-3, x+y=4 and each R is a substituted or unsubstituted alkyl, alkenyl, alkynyl or aromatic group; and Hₓ(RO)_{y}, —Si—Si—(OR)_{y}Hₓ, is a substituted or unsubstituted alkyl, alkenyl, alkynyl or aromatic group.

Further examples of silicon-containing precursors include tetraethyl orthosilicate (TEOS), tetramethoxysilane (TMOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon-containing precursor may comprise a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS).

Further, in some examples, the silicon-containing precursor may be an aminosilane, such as bisdiethylaminosilane, diisopropylaminosilane, bis(t-butylamino) silane (BTBAS), di-sec-butylaminosilane, or tris(dimethylamino)silane (3DMAS). Aminosilane precursors include the following: Hₓ—Si—(NR)_{y}, where x=1-3, x+y=4, and R is a substituted or unsubstituted alkyl, alkenyl, alkynyl or aromatic group or hydride group.

In some examples, a halogen-containing silane may be used such that the silane includes at least one hydrogen atom. Such a silane may have a chemical formula of SiXₐH_{y} where y ≥1. For example, dichlorosilane (H₂SiCl₂) may be used in some examples.

The term “silicon oxide deposition subcycle” may generally represent a sequence of processes used to form a silicon oxide-containing layer in a layered film.

The term “spacer” may generally represent a structure formed on a sidewall of a mandrel that remains after removal of the mandrel in an SAP process. A spacer also may be formed in a negative patterning process by filling a gap with a spacer material (e.g. a layered film), and then etching material from around the spacer material.

The term “substrate” may generally represent any object on which a film can be deposited.

The term “substrate support” may generally represent any structure for supporting a substrate in a processing chamber. Examples comprise chucks, pedestals, and showerhead pedestals used for backside deposition processes.

As mentioned above, semiconductor device manufacturing employs many patterning steps in the fabrication of integrated circuits. SAP processes, such as SADP and SAQP processes, may be used when the desired feature size is smaller than the smallest feature size that can be resolved by photolithography.

Spacer formation is an integral part of SADP and SAQP processes. Low temperature silicon oxide (LT-oxide) is used in some current manufacturing processes to form spacers. Current spacers may have thicknesses greater than approximately 140 Angstroms. However, future generations of semiconductor devices may utilize spacers having thicknesses of less than 100 Angstroms. Spacers with thicknesses of less than 100 Angstroms formed from LT-oxide may tend to lean and/or collapse due at least in part to the mechanical strength of LT-oxide. For example, the modulus of elasticity may be <80 GPa for LT-oxide.

Another concern that arises where spacer thickness is less than 100 Angstroms is etch selectivity. It may be helpful for spacers to possess suitable selectivity to hardmask layers to maintain the feature size and shape after an etching process. Example hardmask layers may include silicon oxynitride, silicon oxycarbide, silicon carbonitride and silicon nitride. However, an LT-oxide may not provide sufficient etch selectivity for use in future generations of semiconductor devices.

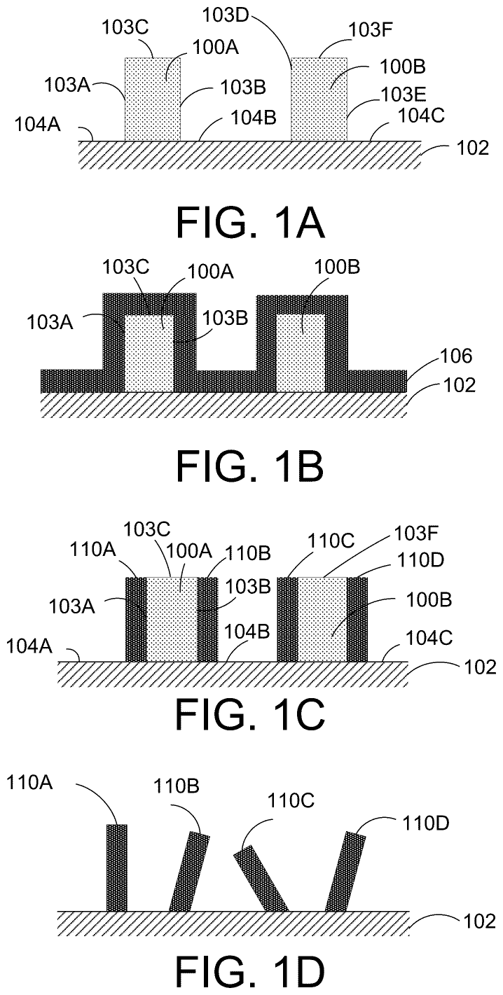

FIGS. 1A-1D illustrate an example of spacer collapse in a spacer formation process. First, FIG. 1A shows mandrels 100A, 100B disposed on a substrate 102. Substrate 102 may represent any suitable structure on which mandrels 100A, 100B, may be formed. Mandrels 100A and 100B include sidewalls 103A, 103B and 103D, 103E, respectively. Mandrels 100A and 100B also include top surfaces 103C, 103F, respectively. Mandrels 100A, 100B are bordered by exposed substrate regions 104A, 104B and 104C. Any suitable material may be used to form the mandrels 100A and 100B. Example materials may comprise polycrystalline silicon, amorphous silicon, silicon nitride, photoresist, spin on carbon, and amorphous carbon.

FIG. 1B illustrates an intermediate structure after a conformal deposition of an example spacer film 106. As illustrated, spacer film 106 is formed on mandrels 100A, 100B and exposed regions (104A, 104B, 104C of FIG. 1A) of substrate 102. The spacer film 106 may be deposited using a vapor phase process such as CVD or ALD. Any suitable vapor phase process that results in a suitably conformal spacer film may be used. Example processes may include plasma-enhanced CVD (PECVD), TCVD, TALD, PEALD or remote PEALD.

Spacer film 106 may be deposited at temperatures that are compatible with the mandrel material. Example deposition may be conducted in the temperature range of 120-400° C. Any suitable material may be used for the spacer film 106. One example comprises LT-oxide.

Referring next to FIG. 1C, portions of the spacer film 106 that are on the top surfaces 103C 103F of mandrels 100A, 100B and substrate regions 104A, 104B, 104C (FIG. 1A) are etched via a directional etch. The etch forms spacers 110A, 110B for mandrel 100A and spacers 110C, 110D for mandrel 100B. Any suitable method for directional etching may be used. Examples of directional etching may include sputtering, ion milling or reactive ion etching (RIE). The directional etching may selectively remove spacer material in planes that are generally parallel to the substrate 102. The directional etching process may be discontinued when the top surfaces 103C and 103F of mandrels 100A and 100B, respectively, are sufficiently exposed.

Referring next to FIG. 1D, mandrels 100A and 100B are selectively removed to leave behind the spacers 110A, 110B, 110C, 110D. For example, where the mandrels 100A, 100B are amorphous carbon, the mandrels may be removed by an ashing process. Likewise, where mandrels 100A, 100B are formed from a silicon-containing material (e.g. polycrystalline silicon), a suitable etching process may be used. Removal of mandrels 100A, 100B leaves spacers 110A, 110B, 110C and 110D on substrate 102.

However, as illustrated, one or more of spacers 110A, 110B, 110C, 110D may lean or collapse after mandrel removal. This collapse may be due at least in part to the mechanical strength of the spacer material. As described above, the mechanical strength of silicon oxide may be <80 GPa. Thus, an LT-oxide may have insufficient mechanical strength for use as spacers having a thickness of equal to or less than 100 Angstroms.

Further, a silicon oxide spacer may not provide sufficient etch selectivity to maintain a desired feature shape and size when the spacer comprises a thickness of equal to or less than 100 Angstroms.

Accordingly, examples are disclosed that relate to the formation of patterning structures that are mechanically robust at thicknesses of 100 Angstroms or less. One example provides a method of forming a patterning structure. The method comprises performing one or more layered deposition cycles to form a layered film comprising a metal oxide. In some examples, the layered film also may comprise a silicon oxide. The method further comprises etching one or more regions of the layered film to form a patterning structure. The resulting patterning structure may comprise sufficient mechanical strength and etch selectivity for use in SAP applications in which a spacer thickness may be 100 Angstroms or less. As described in more detail below, mechanical strength and etching properties may be varied by varying a ratio of metal oxide to silicon oxide. Other properties, such as film bandgap and/or dielectric constant (k), also may be controlled by varying a ratio of metal oxide to silicon oxide. This may allow the disclosed layered films to be used in capacitors for dynamic random access memory (DRAM) and three-dimensional dynamic random access memory (3DDRAM), and as high k gate oxides, among other possible uses.

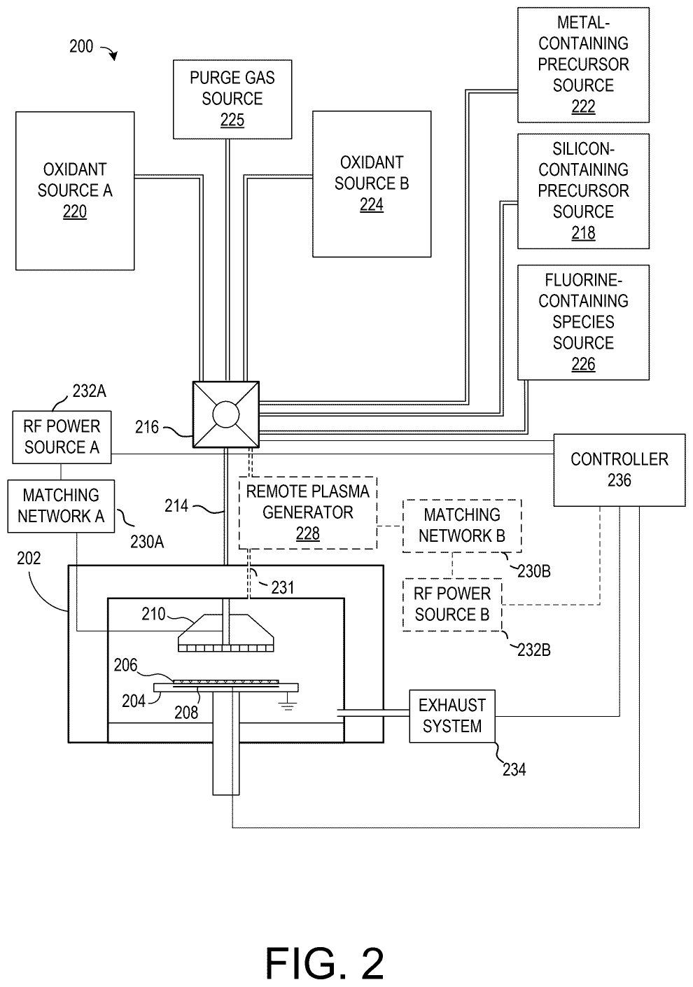

FIG. 2 shows a schematic view of an example processing tool 200 for performing an ALD process to form a layered film. Processing tool 200 comprises a processing chamber 202. Processing tool 200 further comprises a substrate support 204 within the processing chamber for supporting a substrate 206. Substrate support 204 may comprise a pedestal, a chuck, and/or any other suitable structure. Substrate support 204 further may include a substrate heater 208.

Processing tool 200 further comprises one or more processing gas inlets for introducing processing gases into processing chamber 202. One example processing gas inlet is shown a processing gas inlet 214 for admitting a flow of one or more processing gases.

In the depicted example, processing gas inlet 214 directs processes gases to a showerhead 210. In other examples, a nozzle and/or other suitable inlet hardware may be used. Processing tool 200 further comprises flow control hardware 216 for controlling the introduction of processing gases into processing chamber 202. Flow control hardware is connected to a silicon-containing precursor source 218, an oxidant source A 220, a metal-containing precursor source 222, an optional oxidant source B 224, and a purge gas source 225. Where a same oxidant is used for oxidizing the silicon-containing precursor and the metal-containing precursor, oxidant source B 224 may be omitted.

Silicon-containing precursor source 218 comprises any suitable silicon-containing precursor. Example silicon-containing precursors may comprise materials having the general structure:

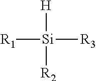

where R₁, R₂ and R₃ may be the same or different substituents, and may include silanes, siloxy groups, amines, halides, hydrogen, or organic groups, such as alkylamines, alkoxy, alkyl, alkenyl, alkynyl and aromatic groups. More specific example silicon-containing precursors include polysilanes (H₃Si—(SiH₂)ₙ—SiH₃), where n ≥1, such as silane, disilane, trisilane, tetrasilane, and trisilylamine. In some examples, the silicon-containing precursor is an alkoxysilane. Alkoxysilanes that may be used include the following: Hₓ—Si—(OR)_{y}, where x=1-3, x+y=4 and each R is a substituted or unsubstituted alkyl, alkenyl, alkynyl or aromatic group; and Hₓ(RO)_{y}, —Si—Si—(OR)_{y}Hₓ, is a substituted or unsubstituted alkyl, alkenyl, alkynyl or aromatic group. Further examples of silicon-containing precursors include tetraethyl orthosilicate (TEOS), tetramethoxysilane (TMOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS). In some examples, the silicon-containing precursor may comprise a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS). Further, in some examples, the silicon-containing precursor may be an aminosilane, such as bisdiethylaminosilane, diisopropylaminosilane, bis(t-butylamino) silane (BTBAS), di-sec-butylaminosilane, or tris(dimethylamino)silane (3DMAS). Aminosilane precursors include the following: Hₓ—Si—(NR)_{y}, where x=1-3, x+y=4, and R is a substituted or unsubstituted alkyl, alkenyl, alkynyl or aromatic group or hydride group. In some examples, a halogen-containing silane may be used such that the silane includes at least one hydrogen atom. Such a silane may have a chemical formula of SiXₐH_{y} where y ≥1. For example, dichlorosilane (H₂SiCl₂) may be used in some examples.

Likewise, metal-containing precursor source 222 comprises any suitable metal. Examples include metal-containing precursors that comprise one or more of aluminum, molybdenum, tungsten or titanium, which respectively may be used to form aluminum oxide (AlOₓ), molybdenum oxide (MoOₓ), titanium oxide (TiOₓ), and tungsten oxide (WOₓ) films. Examples of aluminum-containing precursors for forming aluminum oxide (AlOₓ) include aluminum halides (AlX_{y}), aluminum alkoxide (C₉H₂₁AlO₃), trimethyl aluminum (AlC₃H₉), aluminum carbonyl (Al(CO)ₓ), and aluminum hydride (AlH₃). Examples of molybdenum-containing precursors for forming molybdenum oxide (MoOₓ) include bis(tert-butylimino)bis(dimethylamino) molybdenum (C₁₂H₃₀MoN₄), molybdenum pentachloride (MoCl₅), molybdenum dioxide dichloride(MoCl₅), molybdenum oxytetrachloride (MoOCl₄) and molybdenum hexacarbonyl (Mo(CO)₆). Examples of titanium-containing precursors for forming titanium oxide films (TiOₓ) include titanium tetrachloride (TCl₄) and titanium isopropoxide (Ti(OCH(CH₃)₂)₄). Examples of tungsten-containing precursors for forming tungsten oxide films (WOₓ) include tungsten hexafluoride (WF₆), tungsten hexachloride (WCl₆), bis(tert-butylimino)bis(dimethylamino) tungsten (C₁₂H₃₀N₄W) and tungsten hexacarbonyl (W(CO)₆).

Oxidant source A 220 may comprise any suitable oxidant that may be used to oxidize silicon-containing precursor adsorbed on the substrate during a silicon oxide deposition subcycle. In some examples, oxidant source A 220 may be used to oxidize metal-containing precursor adsorbed on the substrate during a metal oxide deposition subcycle. Likewise, optional oxidant source B 224, when used, may comprise any suitable oxidant that may be used to oxidize a metal precursor adsorbed on the substrate during a metal oxide deposition subcycle. Example oxidants comprise one or more of oxygen (O₂), ozone (O₃), one or more oxides of nitrogen (e.g. N₂O), water vapor (H₂O), or hydrogen peroxide (H₂O₂).

Purge gas source 225 may comprise any suitable inert gas. Examples include one or more of argon, nitrogen, krypton or xenon. In some examples, one or more additional purge gas sources may be included, each providing a different purge gas.

Processing tool 200 further comprises an exhaust system 234. Exhaust system 234 is configured to remove gases from processing chamber 202. Exhaust system 234 may comprise any suitable hardware. Example hardware includes one or low vacuum pumps and/or one or more high vacuum pumps.

In some examples, substrate heater 208 is used to provide thermal energy to facilitate the ALD process. In other examples, a plasma to facilitate the ALD process alternatively or additionally may be generated inside processing chamber 202 using a radiofrequency (RF) power source A 232A and a matching network A 230A. The plasma may be used to provide the energy to generate chemically active species in the gas phase. In other examples, a remote plasma generator 228 may be used to provide reactive species for an ALD process.

The RF source A 232A and the matching network A 230A further may be used to generate active fluorine species from fluorine-containing species source 226. Active fluorine species may be used to clean the processing chamber 202 of build up from layered film deposition cycles. Any suitable fluorine containing fluid may be used as the fluorine-containing species source. Example fluorine containing fluids include NF₃, CF₄ HF, F₂ and C₂F₆.

In other examples, a remote plasma is generated via an optional remote plasma generator 228 to produce reactive species, in addition or alternatively to heating the substrate. The remote plasma may form a reactive and/or intermediate species drive the ALD reaction. Remote plasma generator 228 may be omitted in some examples. Remote plasma generator 228 also may be used to generate active fluorine species from the fluorine-containing species source 226. Any suitable fluorine containing fluid may be used as the fluorine-containing species source. Example fluorine containing fluids include NF₃, CF₄ HF, F₂ and C₂F₆. Active fluorine species may be used for cleaning the processing chamber 202. Chemical species from remote plasma generator 228 may be introduced into processing chamber 202 via gas inlet 231. In other examples, remote plasma generator 228 may be configured to introduce chemical species into processing chamber 202 via gas inlet 214 and showerhead 210.

Where optional remote plasma generator 228 is used, processing tool 200 may further comprise a radiofrequency power source B 232B electrically connected to remote plasma generator 228. Processing tool 200 further may comprise a matching network B 230B for impedance matching of the radiofrequency power source 232B.

Radiofrequency power source A 232A and radiofrequency power source B 232B may be configured for any suitable frequency and power. Examples of suitable frequencies include 400 kHz, 13.56 MHz, 27 MHz, 60 Mz, and 90 MHz. Examples of suitable powers include powers between 50 W (watts) and 50 kW. In some examples, radiofrequency power sources 232A and 232B may be configured to operate at a plurality of different frequencies and/or powers.

Flow control hardware 216 may be controlled to flow processing chemicals from sources 218, 220, 222, 224 and 225 into processing chamber 202 via gas inlet 214. In some examples, flow control hardware 216 may also be configured to control the flow of one or more chemicals into remote plasma generator 228. Flow control hardware 216 schematically represents any suitable components related to flowing gas into processing chamber 202 (and remote plasma generator 228 in some examples). For example, flow control hardware 216 may comprise one or more mass flow controllers and/or valves controllable to place a selected chemical source in fluid connection with processing chamber 202.

Controller 236 is operatively coupled to substrate heater 208, flow control hardware 216, remote plasma generator 228, exhaust system 234, radiofrequency power source A 232A, and radiofrequency power source B 232B. Controller 236 further may be operatively coupled to any other suitable component of processing tool 200. Controller 236 is configured to control various functions of processing tool 200 to perform a layered film deposition process. Controller 236 is also configured to control various functions of the processing tool 200 to perform a chamber cleaning process.

For example, controller 236 is configured to operate substrate heater 208 to heat a substrate. Controller 236 is also configured to operate flow control hardware 216 to flow a selected chemical or mixture of chemicals at a selected rate into processing chamber 202. Controller 236 is also configured to operate exhaust system 234 to remove gases from processing chamber 202. Controller 236 is further configured to operate flow control hardware 216 and exhaust system 234 to maintain a selected pressure within processing chamber 202. Controller 236 is further configured to control the plasma source 232A to control the plasma generated in the chamber. Furthermore, controller 236 is configured to operate optional remote plasma generator 228 and/or radiofrequency power source 232B to form a remote plasma.

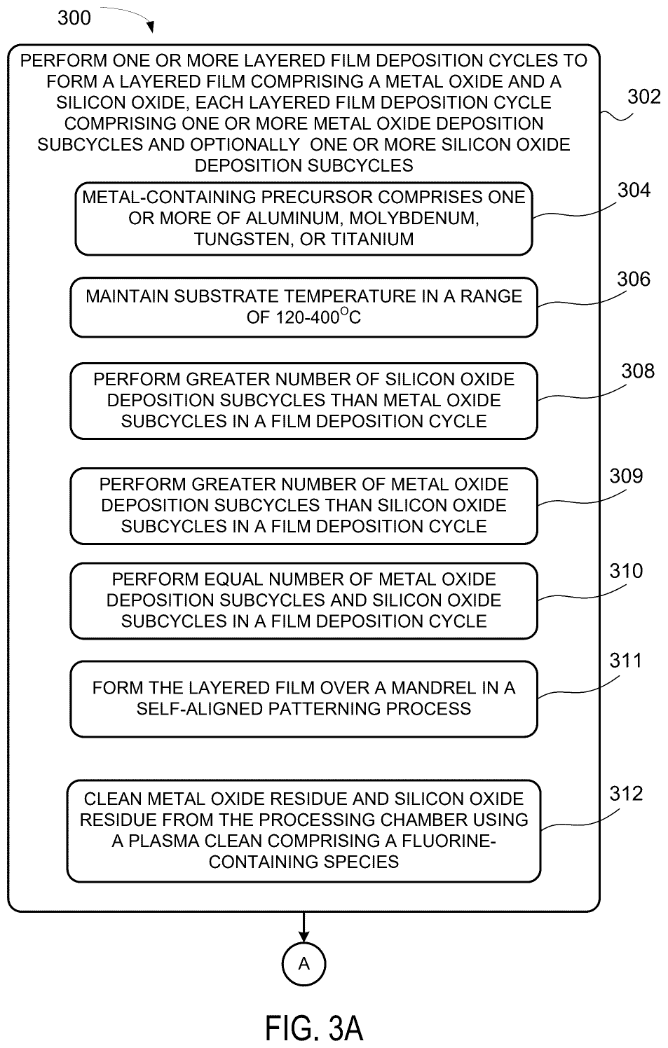

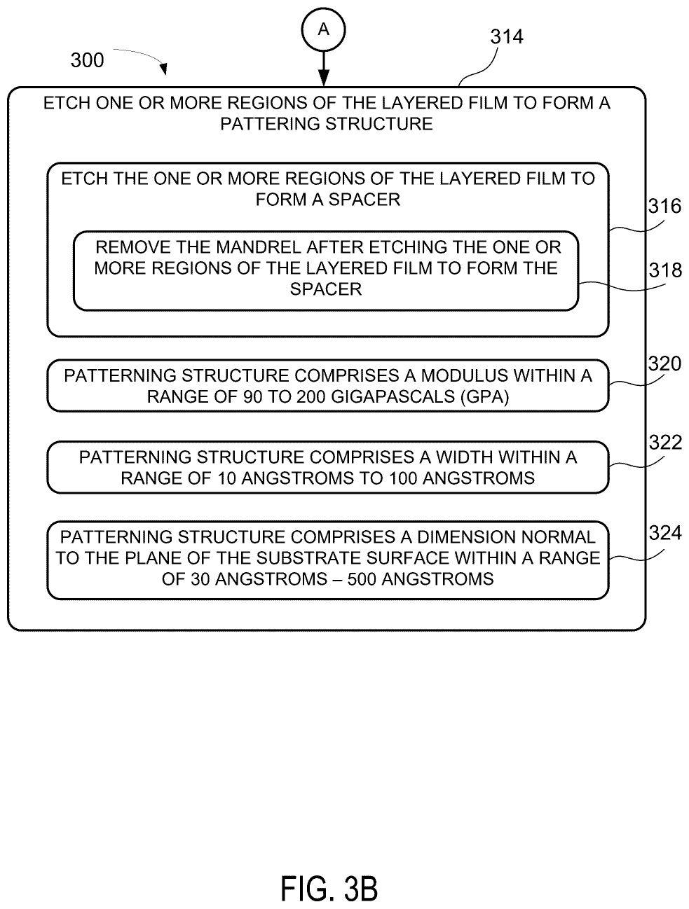

FIGS. 3A and 3B show a flow diagram depicting a method for forming a patterned structure by depositing a layered film and then etching one or more regions of the layered film. First referring to FIG. 3A, method 300 comprises, at 302, performing one or more layered film deposition cycles to form a layered film comprising a metal oxide layer and a silicon oxide layer. Each film deposition cycle comprises one or more metal oxide deposition subcycles. Each film deposition cycle also includes one or more silicon oxide deposition subcycles.

Each silicon oxide deposition subcycle may comprise flowing a silicon-containing precursor in the processing chamber to adsorb silicon-containing precursor to the substrate surface. The silicon oxide deposition subcycle further may comprise purging the chamber with a purge gas after introducing the silicon-containing precursor into the chamber. The silicon oxide deposition subcycle further may comprise forming oxidizing conditions in the processing chamber and oxidizing the silicon precursor adsorbed on the substrate surface to form silicon oxide. The oxidizing conditions may be formed by introducing an oxidant into the processing chamber. In some examples, a plasma may be used to facilitate oxidation of the silicon-containing precursor. Further, in some examples, thermal energy alternatively or additionally may be used to facilitate oxidation of the silicon-containing precursor The silicon oxide deposition subcycle also may comprise again purging the processing chamber after oxidizing the silicon-containing precursor on the substrate surface.

Each metal oxide deposition subcycle may comprise flowing a metal-containing precursor in the processing chamber to adsorb metal-containing precursor to the substrate surface. The metal oxide deposition subcycle further may comprise purging the chamber with a purge gas after introducing the metal-containing precursor into the chamber. The metal oxide deposition subcycle further may comprise forming oxidizing conditions in the processing chamber and oxidizing the metal precursor adsorbed in the substrate surface to form metal oxide. The oxidizing conditions may be formed by introducing an oxidant into the processing chamber. A same oxidant, or different oxidants, may be used in a silicon oxide deposition subcycle and a metal oxide deposition subcycle. In some examples, a plasma may be used to facilitate oxidation of the silicon-containing precursor. Further, in some examples, thermal energy alternatively or additionally may be used to facilitate oxidation of the silicon-containing precursor. The metal oxide deposition subcycle also may comprise purging the processing chamber after oxidizing the metal-containing precursor on the substrate surface.

In some examples, the metal-containing precursor may comprise one or more of aluminum, molybdenum, tungsten or titanium, as indicated at 304. In other examples, the metal-containing precursor may comprise any other suitable metal. Examples of metal-containing precursors are described above. In some examples, energy may be provided to drive the chemical reaction to form the oxides. In some such examples, energy for the chemical reaction may be supplied by heating the substrate in the temperature range of 120-400° C., as indicated in 306. In other examples, the substrate may be heated to any other suitable temperature that is compatible with the processing materials and chemistries. A relatively higher substrate temperature may help avoid forming metal-metal bonds for some metal-containing precursors. A relatively higher substrate temperature may also result in layered films with a relatively higher density and modulus. Alternatively to or additionally to heating the substrate, energy for the chemical reaction may also be supplied by a plasma that is generated in the processing chamber. In some examples, the plasma may be generated when an oxidant flows through the chamber.

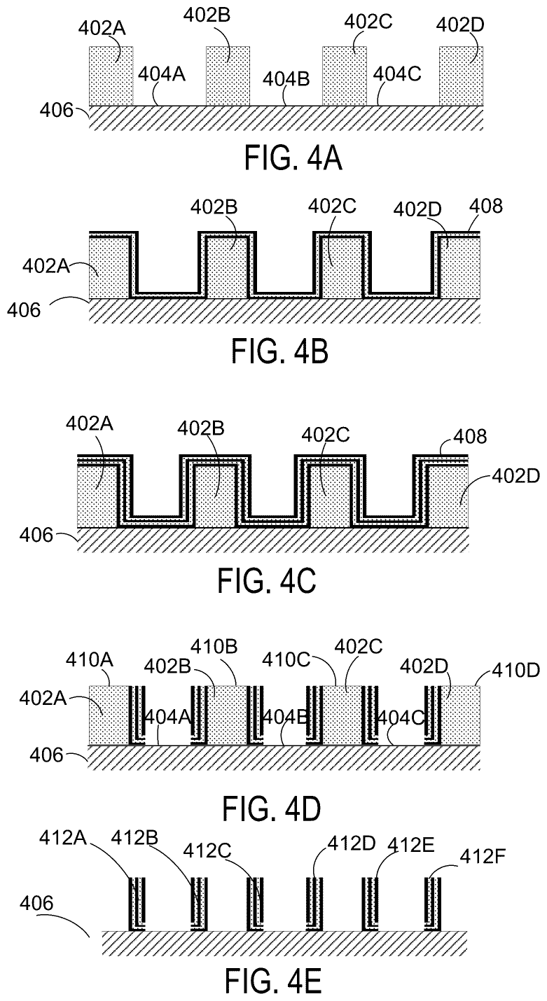

In some examples, the layered films may be deposited over one or more mandrels for spacer formation in a self-aligned patterning process. This is indicated in FIG. 3A at 311. FIGS. 4A-4C show an example deposition of a layered film 408 deposited conformally over mandrels 402A, 402B, 402C, 402D on a substrate 406. Layered film 408 also is deposited over substrate surfaces 404A, 404B, 404C. Any suitable number of layered film deposition cycles may be performed to form a layered film over one or more mandrels. As illustrated by FIGS. 4B and 4C, a thickness of a layered film grows as additional layered film deposition cycles are performed. In other examples, a layered film may be used to fill the gaps between mandrels. In yet other example applications, a layered film may be used to form capacitors for DRAM and 3DDRAM, or high k gate oxides.

In some examples, a ratio of a number of silicon deposition subcycles to a number of metal deposition subcycles may be varied to obtain targeted film properties. Controllable properties of layered films according to the present disclosure may include one or more of modulus of elasticity, etch selectivity, dielectric constant or band gap. In some examples, a greater number of silicon oxide deposition subcycles than metal oxide deposition subycles may be performed in a layered film deposition cycle, as indicated in 308. In other examples, a greater number of metal oxide deposition subcycles than silicon oxide deposition subcycles may be performed in a layered film deposition cycle, as indicated in 309. In further examples, an equal number of metal oxide deposition subcycles and silicon oxide deposition subcycles may be performed in a layered film deposition cycle as indicated in 310. In some examples, increasing the metal oxide content in the layered film may increase the density and/or the modulus of the layered film.

Over time, metal oxide deposition subcycles and silicon oxide deposition subcycles may cause build-up of metal oxide and silicon oxide residues in a processing chamber over time. This build-up may lead to particle and/or defect formation on the substrate surface during a deposition subcycle. The defect and/or particle formation on the substrate surface may result in a yield loss of the integrated device.

Thus, cleaning of the processing chamber may be performed to mitigate risks that arise from particle formation. In some examples, cleaning may be performed after depositing layered films on a number of substrates. In other examples, cleaning may be performed between the metal oxide deposition subcycles and silicon oxide deposition subcycles. Information on defect and/or particle performance, based on repeated processing of the final layered films, may be used to determine a suitable frequency and sequence of chamber cleaning.

In some examples, a plasma clean comprising a fluorine-containing species may be performed to remove the residual metal oxide and silicon oxide from the processing chamber, as indicated in 312. The plasma may provide sufficient energy to the fluorine-containing species to make the fluorine-containing species chemically reactive. Any suitable fluorine containing fluid may be used as the fluorine-containing species source. Example fluorine containing fluids include NF₃, CF₄ HF, F₂ and C₂F₆. The fluorine-containing species may react with built-up materials on the various surfaces of the processing chamber to form volatile products that may be evacuated from the chamber. The cleaning sequence and duration may be automated using a controller in some examples. In other examples, the cleaning sequence may be partially or fully manually controlled.

In some examples, the plasma energy for cleaning may be provided by generating a plasma directly in the processing chamber. In other examples, a remote plasma generator may be used. Thermal energy may also be provided during the cleaning process by heating the substrate holder to a temperature, for example, to a temperature in a range of 120-400° C. In some examples, silicon oxide and metal oxides may be removed during a same plasma clean. For example, molybdenum oxide and tungsten oxide may be removed by reacting with fluorine-containing species during a cleaning process used to remove silicon oxide. More specifically, molybdenum oxide and tungsten oxide may form volatile fluorides under conditions used in a silicon oxide cleaning process.

Referring next to FIG. 3B, method 300 comprises, at 314, etching of one or more regions of the layered film to form a patterning structure. In some examples, etching of one or more regions of the layered film may comprising forming spacers, as indicated in 316. In some such examples, referring to FIG. 4D, directional etching is used to remove layered film from top surfaces of mandrels 402A, 402B, 402C, 402D and substrate surfaces 404A, 404B and 404C. Examples of directional etching may include sputtering, ion milling or reactive ion etching (RIE). The removal of the layered film from the horizontal regions may expose the top surfaces 410A, 410B, 410C, 410D of the mandrels 402A, 402B, 402C, 402D, respectively.

Continuing with FIG. 3B, method 300 comprises, at 318, removing the mandrel after etching. Referring to FIG. 4E, the removal of mandrels 402A, 402B, 402C, 402D forms spacers 412A, 412B, 412C, 412D, 412E, 412F.

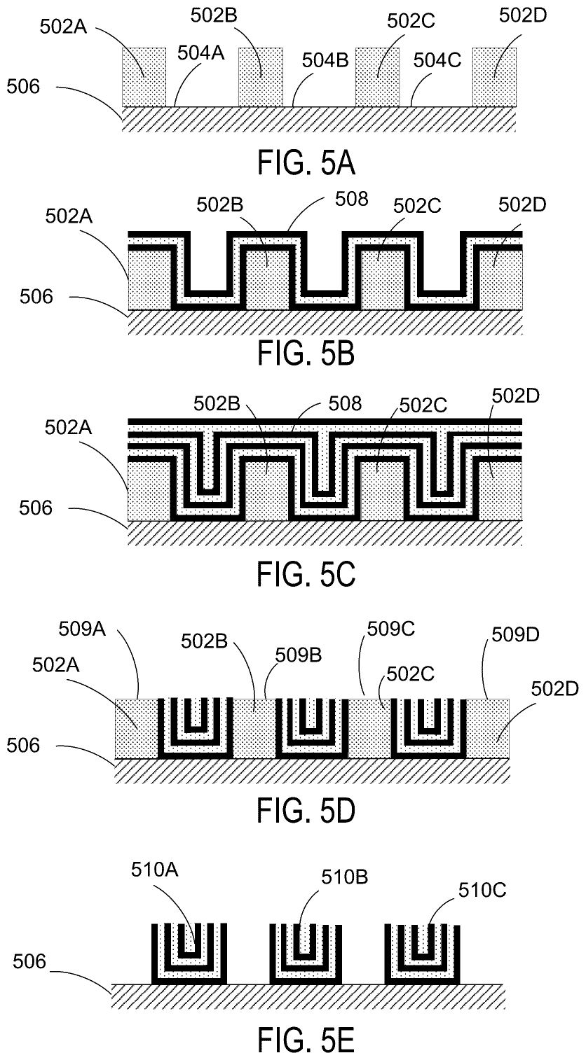

In other examples, layered films may be deposited to fill the gaps between mandrels. FIG. 5A shows mandrels 502A, 502B, 502C, 502D disposed on substrate 506. FIG. 5 B shows a layered film 508 that has been deposited to partially cover the mandrels 502A, 502B, 502C, 502D and partially fill gaps 504A, 504B, 504C between the mandrels. Further deposition cycles may seamlessly fills gaps 504A, 504B, 504C with a layered film 508, as shown in FIG. 5C. Excess layered film 508 on the top surfaces of mandrels 502A, 502B, 502C, 502D may then be removed by a suitable etching process. Referring next to FIG. 5D, the etching process may be discontinued when top surfaces 509A, 509B, 509C, 509D of mandrels 502A, 502B, 502C, 502D have been sufficiently exposed. This may be followed by another suitable etching process that selectively removes mandrels 502A, 502B, 502C, 502D, as described above. Removal of mandrels leaves patterning structures 510A, 510B, 510C remaining on substrate 506, as shown in FIG. 5E.

A spacer formed from layered film according to the present disclosure may comprise a modulus within a range of 90 to 200 GPa, as indicated in 320. The modulus of the layered film spacer may be higher than that of LT oxide spacer, which may be less than 80 GPa. Film density and modulus of the layered films may increase with increase in the deposition temperature. The density and modulus of the layered films may also increase with an increase in the metal oxide content. The higher modulus of the layered material may prevent such spacers from leaning and/or collapsing after removing the mandrels used to form the spacers (e.g. spacers 412A, 412B, 412C, 412D, 412E, 412F in FIG. 4E). This may allow the formation of relatively narrow spacers. In some examples, spacers may comprise a width within a range of 10 Angstroms to 100 Angstroms, as indicated in 322.

In some examples, the patterning structure may comprise a height (a dimension normal to the plane of the substrate surface) within a range of 30 Angstroms to 500 Angstroms, as indicated in 324. In other examples, a patterning structure may have a height outside of this range. The ratio of the dimension normal to the plane of the substrate surface to the width of the spacer may define an aspect ratio (AR) of the patterning structures. The AR for the patterned structure may range from 0.3 to 50. In some examples, an aspect ratio of 3 may be used. In other examples the aspect ratio may be 5. In yet other examples, an aspect ratio of >5 may be used. Spacers with a higher aspect ratio and with a width less than 100 Angstroms may be formed from layered films with a higher modulus. A sufficiently high modulus may prevent the spacers from leaning and/or collapsing.

In some embodiments, the methods and processes described herein may be tied to a computing system of one or more computing devices. In particular, such methods and processes may be implemented as a computer-application program or service, an application-programming interface (API), a library, and/or other computer-program product.

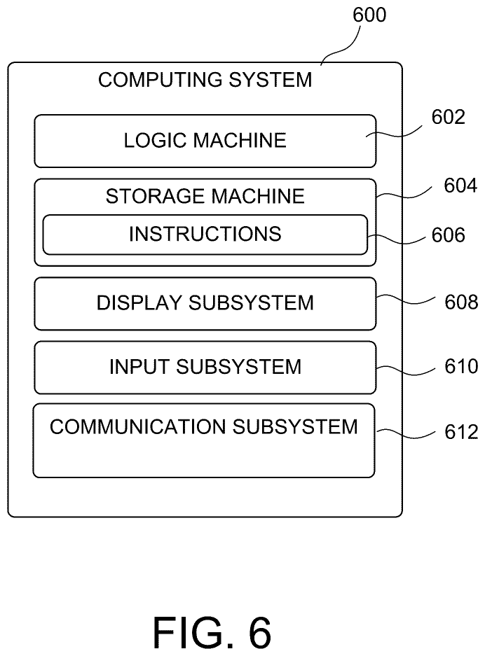

FIG. 6 schematically shows an example of a computing system 600 that can enact one or more of the methods and processes described above. Computing system 600 is shown in simplified form. Computing system 600 may take the form of one or more personal computers, server computers, tablet computers, home-entertainment computers, network computing devices, gaming devices, mobile computing devices, mobile communication devices (e.g., smart phone), and/or other computing devices. Controller 236 in FIG. 2 is an example of computing system 600.

Computing system 600 includes a logic machine 602 and a storage machine 604. Computing system 600 may optionally include a display subsystem 608, input subsystem 610, communication subsystem 612, and/or other components not shown in FIG. 6.

Logic machine 602 includes one or more physical devices configured to execute instructions 606. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 604 includes one or more physical devices configured to hold instructions 606 executable by the logic machine to implement the methods and processes described herein. When such methods and processes are implemented, the state of storage machine 604 may be transformed—e.g., to hold different data.

Storage machine 604 may include removable and/or built-in devices. Storage machine 604 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 604 may include volatile, nonvolatile, dynamic, static, read/write, read-only, random-access, sequential-access, location-addressable, file-addressable, and/or content-addressable devices.

It will be appreciated that storage machine 604 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 602 and storage machine 604 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 608 may be used to present a visual representation of data held by storage machine 604. This visual representation may take the form of a graphical user interface (GUI). As the herein described methods and processes change the data held by the storage machine, and thus transform the state of the storage machine, the state of display subsystem 608 may likewise be transformed to visually represent changes in the underlying data. Display subsystem 608 may include one or more display devices utilizing virtually any type of technology. Such display devices may be combined with logic machine 602 and/or storage machine 604 in a shared enclosure, or such display devices may be peripheral display devices.

When included, input subsystem 610 may comprise or interface with one or more user-input devices such as a keyboard, mouse, or touch screen. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition; as well as electric-field sensing componentry for assessing brain activity.

When included, communication subsystem 612 may be configured to communicatively couple computing system 600 with one or more other computing devices. Communication subsystem 612 may include wired and/or wireless communication devices compatible with one or more different communication protocols. As examples, the communication subsystem may be configured for communication via a wireless telephone network, or a wired or wireless local- or wide-area network. In some embodiments, the communication subsystem may allow computing system 600 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method of forming a patterning structure, the method comprising:
performing one or more layered film deposition cycles to form a layered film comprising a metal oxide and silicon oxide, a layered film deposition cycle of the one or more layered film deposition cycles comprising
a metal oxide deposition subcycle comprising exposing a substrate to a metal-containing precursor and oxidizing the metal-containing precursor adsorbed to the substrate, and
a silicon oxide deposition subcycle comprising exposing the substrate to a silicon-containing precursor and oxidizing the silicon-containing precursor adsorbed to the substrate; and
etching one or more regions of the layered film to form the patterning structure.

2. The method of claim 1, wherein performing one or more layered film deposition cycles comprises performing a plurality of layered film deposition cycles.

3. The method of claim 1, wherein the layered film deposition cycle of the one or more layered film deposition cycles comprises a greater number of silicon oxide deposition subcycles than metal oxide deposition subcycles.

4. The method of claim 2, wherein the layered film deposition cycle of the one or more layered film deposition cycles comprises a greater number of metal oxide deposition cycles than silicon oxide deposition subcycles.

5. The method of claim 2, wherein the layered film deposition cycle of the one or more layered film deposition cycles comprises an equal number of silicon oxide deposition subcycles and metal oxide deposition subcycles.

6. The method of claim 1, wherein etching the one or more regions of the layered film to form the patterning structure comprises etching the one or more regions of the layered film to form a spacer for a self-aligned patterning process.

7. The method of claim 6, wherein forming the spacer comprises forming the layered film over a mandrel, and removing the mandrel after etching the one or more regions of the layered film.

8. The method of claim 1, wherein the metal-containing precursor comprises one or more of aluminum, molybdenum, tungsten, or titanium.

9. The method of claim 1, wherein the metal-containing precursor comprises one or more of an aluminum halide, aluminum alkoxide, trimethyl aluminum, aluminum hydride, aluminum carbonyl, tungsten hexafluoride, tungsten hexachloride, tungsten hexacarbonyl, bis(tert-butylimino)bis(dimethylamino) tungsten, bis(tert-butylimino)bis(dimethylamino) molybdenum, molybdenum pentachloride, molybdenum dioxide dichloride, molybdenum oxytetrachloride, molybdenum hexacarbonyl, titanium tetrachloride, or titanium isopropoxide.

10. The method of claim 1, wherein forming the patterning structure comprises forming a patterning structure comprising a modulus within a range of 90 to 200 gigapascals (GPa).

11. The method of claim 1, wherein forming the patterning structure comprises forming a patterning structure comprising a width within a range of 10 Angstroms to 100 Angstroms.

12. The method of claim 1, wherein the patterning structure comprises a dimension normal to a plane of the substrate surface within a range of 30 Angstroms-500 Angstroms.

13. The method of claim 1 further comprising cleaning metal oxide residue and silicon oxide residue from the processing chamber using a plasma clean comprising a fluorine-containing species.

14. A processing tool, comprising:
a processing chamber;
one or more gas inlets into the processing chamber;
flow control hardware configured to control gas flow through the one or more gas inlets; and
a controller configured to operate the processing tool to perform one or more layered film deposition cycles, wherein
in a silicon oxide deposition subcycle of the layered film deposition cycle, the controller is configured to control the flow control hardware to introduce a silicon-containing precursor into the processing chamber and control the flow control hardware to form oxidizing conditions in the processing chamber, and
in a metal oxide deposition subcycle of the layered film deposition cycle, the controller is configured to control the flow control hardware to introduce a metal-containing precursor into the processing chamber, the metal-containing precursor comprising one or more of molybdenum or tungsten, and control the flow control hardware to form oxidizing conditions in the processing chamber.

15. The processing tool of claim 14, wherein the controller is configured to control the processing tool to perform a greater number of silicon oxide deposition subcycles than metal oxide deposition cycles in a layered film deposition cycle of the one or more layered film deposition cycles.

16. The processing tool of claim 14, wherein the controller is configured to control the processing tool to perform a greater number of metal oxide deposition subcycles than silicon oxide subcycles in a layered film deposition cycle of the one or more layered film deposition cycles.

17. The processing tool of claim 14, wherein the controller is configured to control the processing tool to perform one or more layered film deposition cycles to grow a layered film comprising a thickness of between 10-100 Angstroms.

18. An intermediate structure in a self-aligned patterning process, the intermediate structure comprising:
a substrate; and
a pattern of metal oxide and silicon oxide-containing spacers disposed on the substrate.

19. The intermediate structure of claim 18, wherein a spacer of the pattern of metal oxide and silicon oxide-containing spacers comprises a width within a range of 100 Angstroms to 10 Angstroms.

20. The intermediate structure of claim 18, wherein the metal oxide comprises one or more of aluminum, tungsten, molybdenum or titanium.
